(19) United States
(12) Patent Application Publication
(10) Pub. No.: US 2006/0275953 A1
(43) Pub. Date: Dec. 7, 2006

(54) COPPER STRIKE PLATING METHOD

(75) Inventor: Yoko Ogihara, Nagano-shi, Nagano (JP)

Correspondence Address: RANKIN, HILL, PORTER & CLARK LLP, 4080 ERIE STREET, WILLOUGHBY, OH, 44094-7836, US

(73) Assignee: SHINKO ELECTRIC INDUSTRIES CO., LTD., Nagano-shi (JP)

(21) Appl. No.: 11/421,602

(22) Filed: Jun. 1, 2006

(30) Foreign Application Priority Data
Jun. 2, 2005 (JP) 2005-163068

(51) Int. Cl. H01L 21/00

(52) U.S. Cl. 438/123

(57) ABSTRACT

Upon applying a copper strike plating to a surface of a substrate made of a copper alloy that was subjected to a heat treatment after a degreasing process and an electrolytic activating process are applied to the surface, a pulse current by which a current appears like a series of pulses only on a polarity side onto which a copper metal is deposited on the surface of the substrate is applied to the substrate in the copper strike plating such that a crystal plane showing a maximum value of an X-ray diffraction intensity of a copper strike plating layer formed on the surface of the substrate corresponds to a (111) plane as a crystal plane showing a maximum value of an X-ray diffraction intensity of the copper layer into which metal crystals made of copper are most densely filled.

### TECHNICAL FIELD

The present disclosure relates to a copper strike plating method. More particularly, the present disclosure relates to a copper strike plating method of applying a copper strike plating to a surface of a substrate made of a copper alloy that was subjected to a heat treatment after a degreasing process and an activating process are applied to the surface.

### RELATED ART

In order to improve a bonding ability of the lead frame to the semiconductor element via the wire, and the like, the plating is applied to the lead frame used in the semiconductor device.

In the step of mounting the semiconductor element onto the lead frame, the step of bonding the wire, and the like, a heat load is applied to a plated thin film that is formed on the lead frame by such plating. When this plated thin film is peeled off from the lead frame by the heat load, in some cases an electrical connection between the semiconductor element and the lead frame is damaged. For this reason, in order to prevent the damage of the electrical connection between the semiconductor element and the lead frame even when the heat load is applied to the plated thin film, adhesiveness and heat resistance of the plated thin film must be improved.

Therefore, normally a thin strike plating layer (underlying plating layer) is formed on the lead frame, and then a plating layer of a desired thickness is formed by the electroplating (see Japanese Patent Unexamined Publication No. Sho. 58-113386).

In the related art, the lead frame made of an Fe—Ni alloy with good electrical characteristics was used as the lead frame.

However, in order to meet the demands for a size reduction and a density increase of the semiconductor device, multiple pin and finer pitch are proceeding in the packaging mode of the lead frame. As a result, mechanical characteristics of the lead frame such as the press working performance, and the like are now handled as an issue.

The lead frame made of a copper alloy such as a Cu—Ni—Si alloy, or the like is superior in such mechanical characteristics to the lead frame made of an Fe—Ni alloy in the related art.

Also, since the electrical characteristics of the lead frame made of the copper alloy are excellent rather than those of the Fe—Ni alloy in the related art, recently the lead frames are going to proceed to the lead frame made of the copper alloy.

The lead frame made of the copper alloy having good mechanical characteristics such as the press working performance, and the like can meet the demand for multiple pin and finer pitch.

Meanwhile, normally the heat treatment is applied to the lead frame obtained by the working such as the press working, or the like to remove a machining distortion.

However, when the copper strike plating is applied to the lead frame made of the copper alloy, which underwent such heat treatment, by applying a DC current to form a thin copper strike plating layer (underlying copper plating layer) on the surface of the lead frame, and then an electrolytic plating layer of desired thickness is formed by the electroplating, a plating layer consisting of the copper strike plating layer and the electrolytic plating layer lacks adhesiveness to the lead frame and a heat resistance. The reason for this phenomenon is that metals are contained in the copper alloy constituting the lead frame to exert a harmful influence upon the plating characteristic and thus the adhesiveness of the plating layer to the lead frame is deteriorated.

In order to improve the adhesiveness of the plating layer to the lead frame and the heat resistance of the plating layer, it is important to improve adhesiveness of the copper strike plating layer to the lead frame. Therefore, prior to the plating, a degreasing process, a polishing process, an acid treatment, and an activating process are applied to the surface of the lead frame made of the copper alloy to which the heat treatment was applied.

However, the pretreatment steps executed before the copper strike plating applied to the lead frame made of the copper alloy, which underwent the heat treatment, consumes much time. Thus, the steps of manufacturing the lead frame become complicated and also a production cost of the lead frame is increased.

In addition, it is expected that the adhesiveness of the copper strike plating layer to the lead frame and the heat resistance of the copper strike plating layer should be further improved.

### SUMMARY

The disclosure below describes a copper strike plating method, capable of shortening pretreatment steps as short as possible when a copper strike plating is applied to a substrate made of a copper alloy that was subjected to a heat treatment, and also forming a copper strike plating layer that is able to satisfy adequately an adhesiveness to the substrate and a heat resistance.

As the result of inventor's unremitting studies to solve the above subject, the inventors of the present invention found the fact that a copper strike plating whose adhesiveness to the lead frame and heat resistance are improved can be formed by applying the copper strike plating using a pulse current after only the degreasing process and the activating process are applied to the lead frame made of a copper alloy that was subjected to the heat treatment, and then come to the present invention.

More particularly, a copper strike plating method comprises steps of: applying a degreasing process and an activating process to a surface of a substrate made of a copper alloy that was subjected to a heat treatment; and applying a copper strike plating to the surface of the substrate after the degreasing process and the activating process. In the copper strike plating, a pulse current by which a current appears like a series of pulses only on a polarity side onto which a copper metal is deposited on the surface of the substrate is applied to the substrate such that a crystal plane showing a maximum value of an X-ray diffraction intensity of a copper strike plating layer formed on the surface of the substrate corresponds to a (111) plane as a crystal plane showing a maximum value of an X-ray diffraction intensity of a copper layer into which metal crystals made of copper are most densely filled.

In such present disclosure, the substrate obtained by applying only a degreasing process and an activating process to a substrate made of the copper alloy that underwent a heat treatment is employed as the substrate to which the copper strike plating is applied. Therefore, the pretreatment steps such as the polishing process, and the like can be omitted, and the pretreatment steps can be shortened.

Preferably, a pulse current, a pulse period and a duty ratio t_{ON}/(t_{ON}+t_{OFF}) (where t_{ON} is an ON time in which a current is supplied to the substrate, and t_{OFF} is an OFF time in which a current is shut off) of which are adjusted such that the crystal plane showing the maximum value of the X-ray diffraction intensity of the copper strike plating layer formed on the surface corresponds to the (111) plane, can be employed as the pulse current.

Also, the substrate made of the copper alloy that is formed by adding at least one element selected from a group consisting of Ni, Fe, Sn, Cr, Si and Mg to a matrix formed of copper is employed as the substrate. Therefore, machining performances such as the press working performance, and the like of the substrate can be improved.

In this case, preferably a thickness of the copper strike plating layer should be set to 0.01 to 5 μm.

Various implementations may include one or more the following advantages. For example, according to the copper strike plating method of the present disclosure, the degreasing process and the activating process are applied to the substrate made of the copper alloy that was subjected to the heat treatment, and then the copper strike plating is applied by applying a pulse current by which a current appears like a series of pulses only on the polarity side onto which the copper metal is deposited on the surface of the substrate. Therefore, the copper strike plating layer in which the metal crystals made of copper are densely filled can be formed on the surface of the substrate. The reason for this can be considered as follows.

Since the additive added into the copper alloy are diffused/segregated onto the surface, the surface of the copper alloy, which underwent the heat treatment, shows an uneven distribution state. Hence, according to the copper strike plating executed by applying a DC current to the substrate in the related art, the metal crystals are grown at predetermined locations on the surface of the substrate and thus the copper strike plating layer formed of large-sized metal crystals is formed. In this manner, the copper strike plating layer formed of large-sized metal crystals is inferior in the adhesiveness to the substrate and the heat resistance.

Therefore, in the copper strike plating executed by applying the DC current to the substrate in the related art, the surface of the substrate must be adjusted by applying the polishing process, and the like to fit to the plating.

However, there is a limit to an adjustment of the surface of the substrate. Therefore, the metal crystals of the formed copper strike plating layer are large in size even when the copper strike plating is applied to the substrate to which the polishing process, and the like were applied. Thus, it is extremely difficult to form the copper strike plating layer having a dense structure.

In contrast, in the present disclosure, in the copper strike plating executed by applying the pulse current by which the current appears like a series of pulses only on the polarity side onto which the copper metal is deposited on the surface of the substrate, when the current is to be applied to the substrate, a large voltage can be applied in a moment to the substrate rather than the copper strike plating that is executed by applying the DC current to the substrate. Therefore, generation of the crystal nucleus is caused preferentially and uniformly in the substrate, and as consequence the copper strike plating layer in which the metal crystals are densely filled can be formed.

In this manner, according to the copper strike plating executed by applying the pulse current by which the current appears like a series of pulses only on the polarity side onto which the copper metal is deposited on the surface of the substrate, the generation of the crystal nucleus is caused preferentially and uniformly in the substrate. Therefore, even when the surface of the substrate is in an uneven condition, the copper strike plating layer in which the metal crystals are densely filled and the adhesiveness to the substrate and the heat resistance of which are improved can be formed. As a result, the polishing process, and the like to be applied as the pretreatment steps prior to the strike plating can be omitted.

Other features and advantages may be apparent from the following detailed description, the accompanying drawings and the claims.

### BRIEF DESCRIPTION OF THE DRAWINGS

FIG. 1 is a schematic view of an electroplating equipment used in the present invention.

FIG. 2 is explanatory views explaining pulse currents used in the present invention.

FIG. 3 is a graph showing an X-ray diffraction pattern of a copper strike plating layer obtained by the present invention.

FIG. 4 is electron microphotographs showing a sectional structure of the copper strike plating layer obtained by the present invention respectively.

FIG. 5 is a graph showing an X-ray diffraction pattern of the copper strike plating layer formed by using a DC current.

FIG. 6 is electron microphotographs showing a sectional structure of the copper strike plating layer formed by using a DC current.

FIG. 7 is an explanatory view explaining an internal structure of a copper alloy.

FIG. 8 is a graph showing a X-ray diffraction pattern of a Ni plating layer obtained by using THRUNIC C (produced by Uyemura & Co., Ltd) as a nickel plating bath.

FIG. 9 is a graph showing a X-ray diffraction pattern of a Ni plating layer obtained by using nickel sulfamate as the nickel plating bath.

### DETAILED DESCRIPTION

As the substrate used in the present invention, the substrate made of the copper alloy whose workability such as the press working performance is excellent is used. As such substrate, the substrate made of Cu—Fe alloy, Cu—Ni—Si alloy, Cu—Cr alloy, and Cu—Sn alloy can be listed. In particular, preferably the substrate made of the copper alloy, which is formed by adding at least one element selected from a group consisting of Ni, Fe, Sn, Cr, Si and Mg to the matrix formed of copper, should be employed.

Especially the substrate made of the copper alloy, which contains at least one of Mg and Si as the additive or its accompanying product, can be employed preferably.

In the substrate made of such copper alloy, alloys are made from the additive, etc. and the copper and are dispersed to grain boundaries between metal crystals.

When a machining distortion caused due to the working such as the press working, or the like is accumulated, normally a heat treatment is applied to the substrate made of such copper alloy to remove the machining distortion.

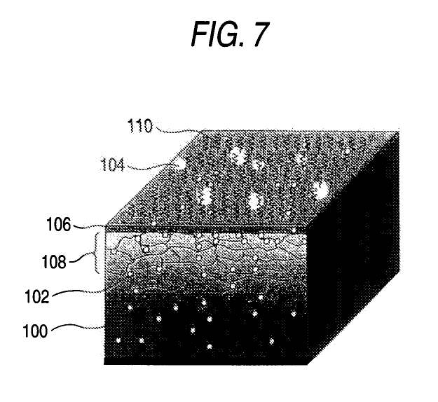

In the substrate made of the copper alloy, as shown in FIG. 7, the alloys 102 dispersed to grain boundaries 100 in the inner side of the substrate are diffused/segregated onto a surface of the substrate by this heat treatment. Then, such alloys 102 construct smuts 104 after the polishing process, and make a surface of the substrate uneven.

Also, a deteriorated layer 106 is formed on a surface of the substrate by the heat treatment. Also, an affected layer 108 is formed near the surface. In particular, when at least one of Mg and Si is contained in the copper alloy constituting the substrate, Mg and Si segregated onto the surface are prone to form the deteriorated layer that has insufficient conductivity.

Such deteriorated layer 106 as well as the smuts 104 and organic stains 110 formed on the surface of the substrate constitutes an obstacle to the copper strike plating that is applied to the surface of the substrate by using a DC current.

Therefore, in the related art, the smuts 104, the deteriorated layer 106, and the organic stains 110 must be removed prior to the strike plating. As such removing means, a degreasing process and an electrolytic activating process are applied to the surface of the substrate after a polishing process is applied. Since the smuts 104 still remain on the surface of the substrate after a series of processes are applied, such smuts 104 are removed by an acid treatment.

In contrast, in the present invention, merely the degreasing process and the activating process are applied to the surface of the substrate made of the copper alloy to which the heat treatment was applied, and then the copper strike plating layer into which metal crystals are filled densely can be formed on the surface of the substrate by the copper strike plating using a pulse current. The copper strike plating layer is excellent in the adhesiveness to the substrate and the heat resistance.

Here, as the heat treatment applied to the substrate, publicly-known heat treatment conditions can be employed to remove the machining distortion. Also, the degreasing process and the activating process applied to the substrate can be executed by using the publicly-known processing agents and under the publicly-known processing conditions.

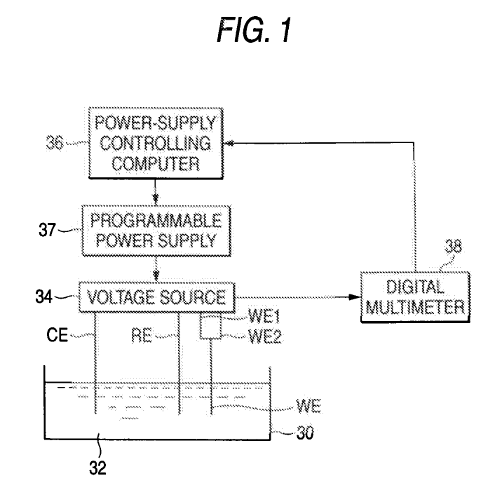

The copper strike plating using the pulse current can be applied by an electroplating equipment shown in FIG. 1. In the electroplating equipment shown in FIG. 1, an anode CE, cathodes WE₁, WE₂ connected to a substrate WE, and a reference electrode RE are inserted into a plating bath 32 in a plating tab 30. The cathode WE₂ as well as the cathode WE₁ is connected to the substrate WE. The anode CE, the cathodes WE₁, WE₂, and the reference electrode RE are connected to a voltage source 34. A voltage is supplied from the voltage source 34.

A control signal is issued from a programmable power supply 37 that is controlled by a power-supply controlling computer 36. A predetermined voltage is supplied to the anode CE and the cathode WE₁ from the voltage source 34 based on this control signal. Such voltage is controlled based on a potential difference between the reference electrode RE and the cathode WE₂.

Also, a current flowing from the anode CE to the cathode WE₁ is monitored by a digital multi meter 38. Then, a monitored current value is fed back to the power-supply controlling computer 36. Since such current value is almost proportional to a thickness of a copper strike plating thin film that is formed on the surface of the substrate WE connected to the cathode WE₁, the power-supply controlling computer 36 controls the programmable power supply 37 based on the current value that is monitored by the digital multi meter 38.

In this case, a commercial plating solution for the copper strike plating can be employed as the plating bath 32.

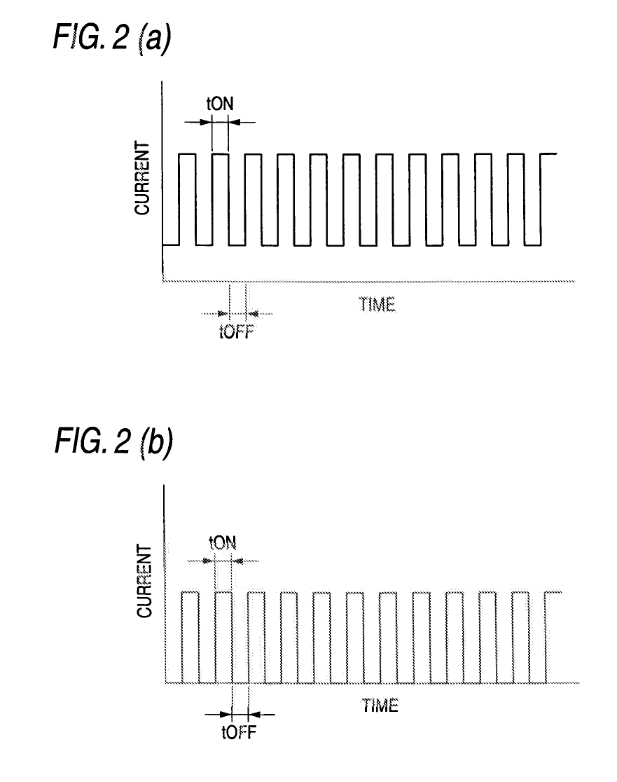

A pulse current applied to the substrate WE is a pulse current by which a current appears like a series of pulses only on the polarity side onto which a copper metal is deposited on the surface of the substrate WE, and is shown in FIGS. 2(a)(b). A pulse current in FIG. 2(a) shows a pulse current that applies a constant current to the substrate WE and superposes a predetermined current in a pulse fashion. Also, a pulse current in FIG. 2(b) shows a pulse current that reduces the applied current to zero after a predetermined current is supplied in a pulse fashion to the substrate WE.

The pulse current is adjusted in such a way that a crystal plane showing a maximum value of an X-ray diffraction intensity of the copper strike plating layer formed on the surface of the substrate WE corresponds to a (111) plane as a crystal plane showing a maximum value of an X-ray diffraction intensity of the copper layer into which the metal crystals made of copper are most densely filled.

More concretely, preferably the pulse current should be adjusted based on a pulse period and a duty ratio t_{ON}/(t_{ON}+t_{OFF}). The current is supplied to the substrate WE in an ON time (t_{ON}), while the current is shut off in an OFF time (t_{OFF}). In particular, preferably the pulse current should be adjusted under conditions that the pulse period is set in a range of 10 to 1000 Hz and the duty ratio is set in a range of 0.2 to 0.5.

It is preferable that a thickness of the copper strike plating layer obtained by such pulse current should be set to almost 0.01 to 5 μm.

Also, it is preferable that a current density of the pulse current should be adjusted such that a current efficiency of the copper deposition becomes about 30%.

The metal crystals made of copper are filled densely in the copper strike plating layer formed on the surface of the substrate WE in this manner. Also, this copper strike plating layer has a good heat resistance of the adhesive characteristic to the substrate WE.

In the related art, in the substrate WE made of the copper alloy, especially the copper alloy containing at least one of MG and Si, since Mg or Si is diffused/segregated onto the surface of the substrate when the heat treatment is applied to remove the machining distortion, or the like, the deteriorated layer having insufficient conductivity is easily formed. Therefore, in the related art, unless the pretreatment steps such as the polishing process, and the like are applied to remove the deteriorated layer that is formed on the surface of the substrate WE and lacks the conductivity, the copper strike plating cannot be applied to the substrate WE made of the copper alloy, which underwent the heat treatment.

On the contrary, according to the copper strike plating method of the present invention, as the pretreatment steps applied prior to the copper strike plating, it is enough just to apply the degreasing process and the activating process to the substrate WE made of the copper alloy, which underwent the heat treatment. Therefore, in the present invention, the pretreatment steps can be shortened sufficiently rather than that in the related art.

Any metal plating layer such as a copper plating layer, a silver plating layer, or the like can be formed on the copper strike plating layer formed on the surface of the substrate WE by the electroplating. The metal plating layer can be formed uniformly, the anomalous deposition of the plating metal is not generated, and the heat resistance of the metal plating layer is good.

As this substrate WE, the electronic parts substrate such as the lead frame, or the like can be employed preferably. Thus, the assembling performance of the electronic parts can be improved.

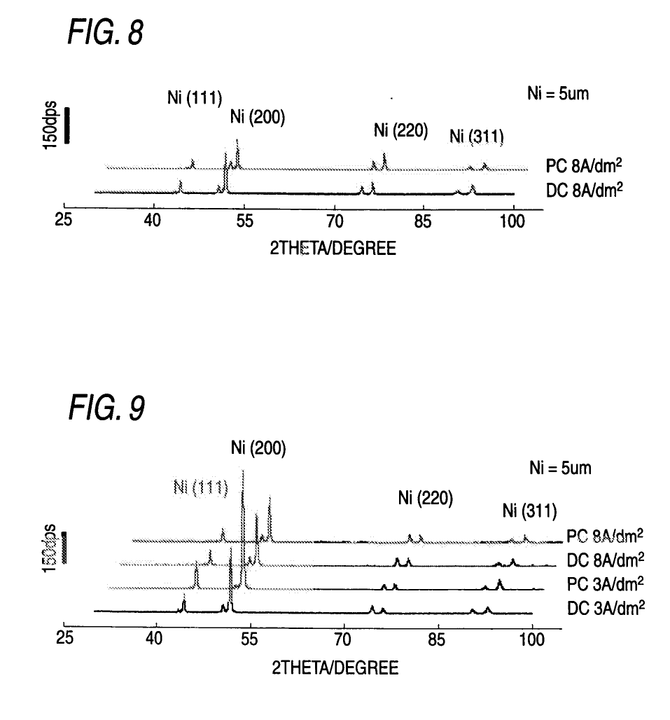

By the way, the so-called reverse current pulse current, i.e., the current supplied to the polarity side at which a copper metal is deposited on the surface of the substrate WE and the current supplied to the polarity side at which the copper metal deposited on the surface of the substrate WE is liquated out are applied alternately to the substrate WE, can be considered as the pulse current (See, Japanese Patent Unexamined Publication No. 2004-339584 which uses the reverse current pulse current to form the roughened Ni plating layer on the metal substrate). However, there is a possibility that, when the reverse current pulse current is applied to the substrate WE, components constituting the substrate WE, and the like dissolve in the plating bath 32 to produce a harmful influence upon the copper strike plating. The above-mentioned Japanese Patent Unexamined Publication No. 2004-339584 also shows to use the pulse current the polarity of which is not reversed to form the Ni plating layer before the roughened Ni plating layer. However, even if such the Ni plating layer is formed on the metal substrate by the pulse current under the pulse condition of t_{ON}<t_{OFF}, a crystal plane showing a maximum value of an X-ray diffraction intensity of the Ni plating layer formed on the substrate does not correspond to a (111) plane as a crystal plane showing a maximum value of an X-ray diffraction intensity of the copper layer into which the metal crystals made of copper are most densely filled (See FIGS. 8 and 9). Therefore, the Ni plating layer in which metal crystals are densely filled can not be formed, compared with the copper strike plating layer of the present invention. FIGS. 8 and 9 show graphs showing X-ray diffraction patterns of the Ni plating layers which are formed on the substrate used in below-described Example 1 by applying a pulse current (PC) under the pulse condition of t_{ON}<t_{OFF} or direct current (DC) with using THRUNIC C (produced by Uyemura & Co., Ltd) (FIG. 8) or nickel sulfamate (FIG. 9) as a nickel plating bath.

In the above explanation, after merely the degreasing process and the activating process are applied to the substrate WE made of the copper alloy that was subjected to the heat treatment, the copper strike plating is applied by applying the pulse current to the substrate WE. In this case, after the polishing process, the degreasing process, the acid treatment, and the activating process are applied to the substrate WE, the copper strike plating may be applied by applying the pulse current to the substrate WE.

### EXAMPLE 1

The lead frame was obtained as the substrate by applying the press working to the stripe member made of the Cu—Ni—Si alloy (Corson alloy) that contains Mg at 0.15 wt %. Then, the heat treatment was applied to remove the machining distortion of the lead frame. Then, only the alkaline degreasing process and the electrolytic activating process were applied to this lead frame.

Then, while using the electrolytic copper plating equipment shown in FIG. 1, the lead frame was inserted as the substrate WE into the plating tab 30 in which an electrolytic copper plating solution is accumulated, and then the copper strike plating was applied to the surface of the lead frame by applying the pulse current.

In the copper strike plating at this time, a pulse period of the pulse current was set to 100 Hz and also an average current density (C.D.) was set to 7 A/dm². Then, the copper strike plating layer of 0.5 μm thickness was formed while changing the duty ratio from 0.2 to 1.0. Respective appearances of the formed copper strike plating layers are given in Table 1.

Then, a silver plating layer of 5 μm thickness was formed on the copper strike plating layer, which was formed on the lead frame and had a thickness of 0.5 μm, by the electrolytic silver plating using an electrolytic silver plating solution available on the market. The results of the visual observation about the appearance of the copper strike plating layer and the appearance of this silver plating layer and occurring extents of nodule (surface roughness), level difference, and unevenness of gloss indicating the Ag anomalous deposition are also given in Table 1. In Table 1, ◯ denotes good, Δ denotes that the anomalous deposition was recognized slightly, and X denotes that the anomalous deposition was recognized.

TABLE 1

| | | | | Ag Anomalous Deposition | | |
|---|---|---|---|---|---|---|
| | Duty | Appearance | Appearance | | | Un- |
| No. | Ratio | of Cu layer | of Ag layer | Nodule | L.D. | evenness |
| 1 | 0.1 | Semi-bright | Semi-bright | ◯ | ◯ | ◯ |
| 2 | 0.4 | Semi-bright | Semi-bright | ◯ | ◯ | ◯ |
| 3 | 0.5 | Semi-bright | Semi-bright | ◯ | ◯ | ◯ |
| 4 | 0.6 | Red matt | Semi-bright | ◯ | Δ − ◯ | ◯ |
| 5 | 0.8 | Red matt | Semi-bright | Δ − ◯ | Δ − ◯ | ◯ |
| 6 | 1.0 | Red matt | Semi-bright | Δ − ◯ | Δ − ◯ | ◯ |

Note)
L.D.; level difference

As apparent from Table 1, even though the polishing was not applied to the lead frame that was subjected to the heat treatment, the good copper strike plating layer could be formed when the duty ratio was 0.5 or less. Thus, the good silver plating layer could be formed on the copper strike plating layer.

In this case, the copper strike plating tended to become the burn plating when the duty ratio was in excess of 0.5. But such copper strike plating layer could be put to practical use.

### EXAMPLE 2

In Example 2, the copper strike plating and the electrolytic silver plating were applied in the similar manner to Example 1 except that the pulse period was changed as shown in Table 2 while keeping the duty ratio at 0.4. The results of the visual observation about the appearance of the copper strike plating layer and the appearance of the silver plating layer and occurring extents of nodule (surface roughness), level difference, and unevenness of gloss indicating the Ag anomalous deposition are also given in Table 2. In Table 2, ◯ denotes good, Δ denotes that the anomalous deposition was recognized slightly, and X denotes that the anomalous deposition was recognized.

TABLE 2

| | | | | Ag Anomalous Deposition | | |
|---|---|---|---|---|---|---|
| | Period | Appearance | Appearance | | | Un- |
| No. | (Hz) | of Cu layer | of Ag layer | Nodule | L.D. | evenness |
| 1 | 1 | ◯ | ◯ | ◯ | ◯ | ◯ |
| 2 | 10 | ◯ | ◯ | ◯ | ◯ | ◯ |
| 3 | 100 | ◯ | ◯ | ◯ | ◯ | ◯ |
| 4 | 1000 | ◯ | ◯ | ◯ | ◯ | ◯ |

As apparent from Table 2, even though the polishing was not applied to the lead frame that was subjected to the heat treatment, the good copper strike plating layer could be formed when the pulse period was changed from 1 to 1000 Hz. Thus, the good silver plating layer could be formed on the copper strike plating layer.

### COMPARATIVE EXAMPLE 1

In Comparative Example 1, the copper strike plating and the electrolytic silver plating were applied to the lead frame similarly to Example 1 except that a DC current was employed in place of the pulse current supplied to the lead frame.

The formed copper strike plating layer showed a red matt appearance. This copper strike plating belonged to a category of the burn plating. Also, the formed silver plating layer showed a semi-bright appearance and the unevenness of gloss was not found, nevertheless the nodule (surface roughness) and the level difference indicating the Ag anomalous deposition were found.

### EXAMPLE 3

In Example 3, the plating was applied to the lead frame by setting other conditions similarly to Example 1 except that the copper strike plating layer of 0.1 μm thickness was formed by applying the copper strike plating under conditions that the pulse period of the pulse current supplied to the lead frame was set to 100 Hz, the average current density (C.D.) was set to 7 A/dm², and the duty ratio was set to 0.4 and that the silver plating layer of 3 to 5 μm thickness was formed on this copper strike plating layer by the electrolytic silver plating.

Then, a copper oxide film was formed on the lead frame that was subjected to the plating under the heating condition given in Table 3, and then a tape peeling test to check whether or not the plating layer is peeled off was executed by peeling off an adhesive tape stuck on the lead frame. In this manner, the adhesiveness of the copper strike plating layer to the oxide film was evaluated. The results of the evaluation are also given in Table 3.

TABLE 3

| | Heating Condition | | | |
|---|---|---|---|---|
| | 280° C. × | | | 340° C. × |
| | 10 min | 300° C. × 10 min | 320° C. × 10 min | 10 min |
| Tape | ◯ | ◯ | ◯ | X |
| Peeling | | | | |
| Result | | | | |

Note)
◯; the peeling-off of the copper oxide film was not found, and
X; the peeling-off of the copper oxide film was found.

As apparent from Table 3, the peeling-off of the copper oxide film was not found up to the heating condition of 320° C.×10 min. But the peeling-off of the copper oxide film was found when the heating condition was 340° C.×10 min.

However, since the silver plating layer of 3 to 5 μm thickness was formed on the copper strike plating layer having a thickness of 0.3 μm by the electrolytic silver plating, the peeling-off of the copper oxide film was not found by the tape peeling test after the copper oxide film was formed under the heating condition of 340° C.×10 min.

The level of Example 3 indicates the fact that, even when the oxide film was formed on the surface of the copper strike plating layer formed on the lead frame, the adhesiveness of the copper strike plating layer to the lead frame was never degraded.

Here, it has been made empirically clear that the lead frame, which has the good adhesiveness to the copper oxide film formed on the surface of the copper strike plating layer in such tape peeling test, has also the good adhesiveness to a mold resin and a semiconductor device.

### COMPARATIVE EXAMPLE 2

The lead frame was obtained as the substrate by applying the press working to the stripe member made of the Cu—Ni—Si alloy (Corson alloy) that contains Mg at 0.15 wt %. Then, the heat treatment was applied to remove the machining distortion of the lead frame. Then, the alkaline degreasing process, the polishing process, the acid cleaning process, the chemical polishing process, and the electrolytic activating process were applied to this lead frame that was subjected to the heat treatment to remove the machining distortion.

Then, while using the electrolytic copper plating equipment shown in FIG. 1, the lead frame to which the alkaline degreasing process, the polishing process, the acid cleaning process, the chemical polishing process, and the electrolytic activating process were applied was inserted as the substrate WE into the plating tab 30 in which the electrolytic copper plating solution is accumulated. Then, the copper strike plating was applied to the surface of the lead frame to get a thickness of 0.1 μm by applying the DC current having an average current density (C.D.) of 7 A/dm² to the lead frame.

Then, the silver plating layer of 3 to 5 μm thickness was formed on the copper strike plating layer, which was formed on the lead frame and had a thickness of 0.1 μm, by the electrolytic silver plating using the electrolytic silver plating solution available on the market.

Then, like Example 3, the adhesiveness of the copper strike plating layer to the copper oxide film was evaluated by applying the tape peeling test to the lead frame that was subjected to the plating. The results of the evaluation are also given in Table 4.

TABLE 4

| | Heating Condition | | | |
|---|---|---|---|---|
| | 280° C. × | | | 340° C. × |
| | 10 min | 300° C. × 10 min | 320° C. × 10 min | 10 min |
| Tape | X | X | X | — |
| Peeling | | | | |
| Result | | | | |

Note)
◯; the peeling-off of the copper oxide film was not found, and
X; the peeling-off of the copper oxide film was found.

As apparent from Table 4, since the peeling-off of the copper oxide film was found even in the heating condition of 320° C.×10 min, the tape peeling test in the heating condition of 340° C.×10 min was stopped.

In this case, even though the silver plating layer of 3 to 5 μm thickness was formed on the copper strike plating layer of 0.3 μm thickness by the electrolytic silver plating, the peeling-off of the copper oxide film was still found by the tape peeling test after the copper oxide film was formed in the heating condition of 280° C.×10 min.

The level of Comparative Example 2 indicates the fact that the copper oxide film that was formed on the surface of the copper strike plating layer formed on the lead frame degraded the adhesiveness of the copper strike plating layer to the lead frame.

Here, it has been made empirically clear that the lead frame, which is inferior in the adhesiveness to the copper oxide film formed on the surface of the copper strike plating layer in such tape peeling test, is also inferior in the adhesiveness to a mold resin and a semiconductor device.

### EXAMPLE 4

(1) The lead frame was obtained as the substrate by applying the press working to the stripe member made of the Cu—Ni—Si alloy (Corson alloy) that contains Mg at 0.15 wt %. Then, the heat treatment was applied to remove the machining distortion of the lead frame. Only the alkaline degreasing process and the electrolytic activating process were applied to this lead frame.

Then, in the electrolytic copper plating equipment shown in FIG. 1, the lead frame to which only the degreasing process and the electrolytic activating process were applied was inserted as the substrate WE into the plating tab 30. Then, the copper strike plating was applied on the surface of the lead frame to get a thickness of 5 μm by applying the pulse current, the pulse period of which was set to 100 Hz and also the average current density (C.D.) of which was set to 7 A/dm², to the lead frame. At this time, the duty ratio was set to 0.4.

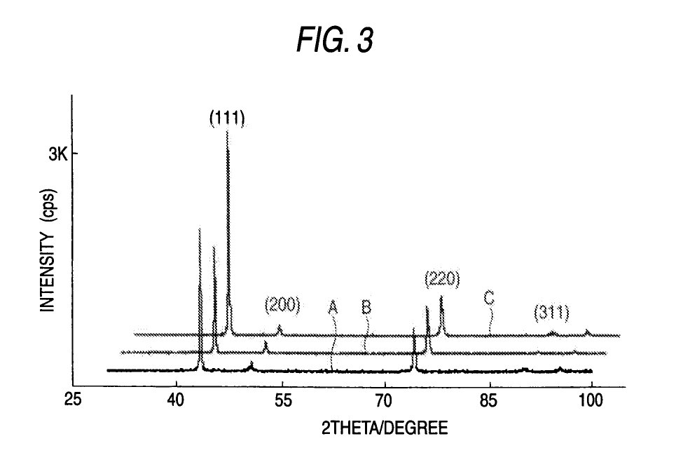

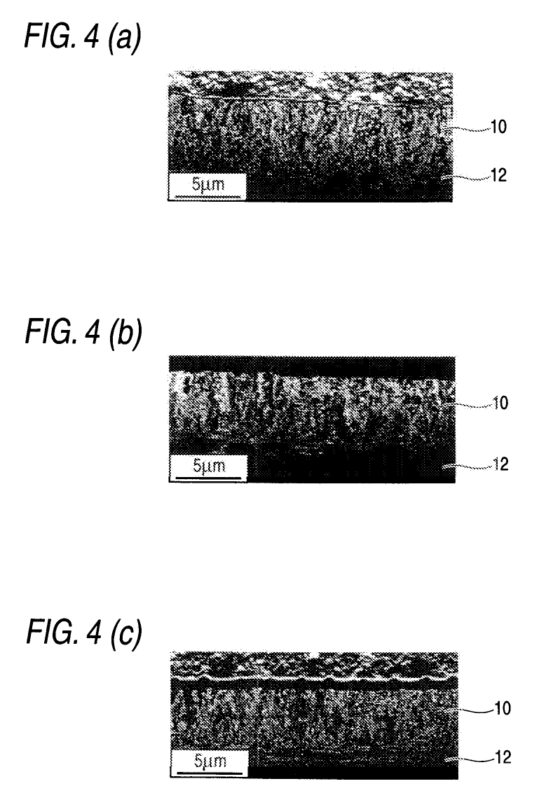

An X-ray diffraction pattern of this copper strike plating layer is shown by a pattern A in FIG. 3. An electron microphotograph of a sectional structure of this copper strike plating layer is shown in FIG. 4(c).

(2) The polishing process, the degreasing process, and the electrolytic activating process were applied to the lead frame used in the above (1). Then, the copper strike plating was applied in the similar manner to the above (1).

An X-ray diffraction pattern of this copper strike plating layer is shown by a pattern B in FIG. 3. An electron microphotograph of a sectional structure of this copper strike plating layer is shown in FIG. 4(b).

(3) The polishing process, the degreasing process, the electrolytic activating process, and the acid treatment were applied to the lead frame used in the above (1). Then, the copper strike plating was applied in the similar manner to the above (1).

An X-ray diffraction pattern of this copper strike plating layer is shown by a pattern C in FIG. 3. An electron microphotograph of a sectional structure of this copper strike plating layer is shown in FIG. 4(a).

In this case, in the electron microphotographs shown in FIGS. 4(a) to 4(c), a longitudinally striped portion indicates a copper strike plating layer 10, and a laterally striped portion located under the copper strike plating layer 10 indicates a surface layer portion 12 of the lead frame.

All the copper strike plating layers in this Example 4 have the semi-bright appearance. As apparent from the X-ray diffraction pattern shown in FIG. 3, all crystal planes, which shows the maximum value of the X-ray diffraction intensity, of the copper strike plating layers in this Example 4 correspond to a (111) plane respectively. This crystal plane is a crystal plane that shows the maximum value of the X-ray diffraction intensity of the copper layer into which the metal crystals made of copper are most densely filled. Therefore, the copper metal crystals are filled densely in the copper strike plating layers of this Example 4.

Also, as apparent from the electron microphotographs in FIG. 4 showing the sectional structure of the copper strike plating layer of this Example 4, small metal crystals made of copper completely are densely filled and an upper surface of the copper strike plating layer constitutes a smooth surface.

### COMPARATIVE EXAMPLE 3

(1) In Comparative Example 3, the copper strike plating layer was formed in the same manner as Example 4(1) except that the copper strike plating was applied to the surface of the lead frame to get a thickness of 5 μm by applying the DC current the average current density (C.D.) of which was set to 7 A/dm².

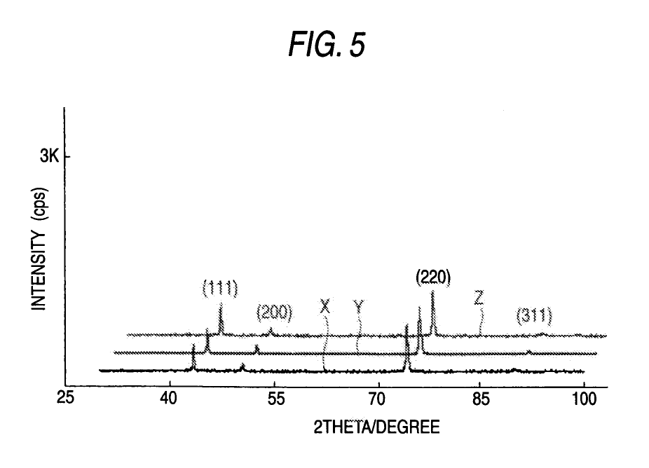

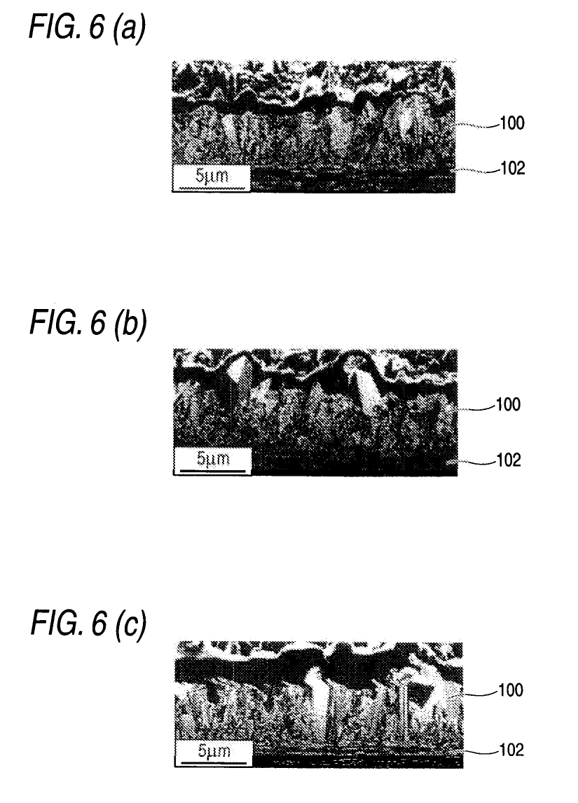

An X-ray diffraction pattern of this copper strike plating layer is shown by a pattern X in FIG. 5. An electron microphotograph of a sectional structure of this copper strike plating layer is shown in FIG. 6(c).

(2) The polishing process, the degreasing process, and the electrolytic activating process were applied to the lead frame used in the above (1). Then, the copper strike plating was applied in the similar manner to the above (1).

An X-ray diffraction pattern of this copper strike plating layer is shown by a pattern Y in FIG. 5. An electron microphotograph of a sectional structure of this copper strike plating layer is shown in FIG. 6(b).

(3) The polishing process, the degreasing process, the electrolytic activating process, and the acid treatment were applied to the lead frame used in the above (1). Then, the copper strike plating was applied in the similar manner to the above (1).

An X-ray diffraction pattern of this copper strike plating layer is shown by a pattern Z in FIG. 5. An electron microphotograph of a sectional structure of this copper strike plating layer is shown in FIG. 6(a).

In this case, in the electron microphotographs shown in FIGS. 6(a) to 6(c), a longitudinally striped portion indicates a copper strike plating layer 100, and a laterally striped portion located under the copper strike plating layer 100 indicates a surface layer portion 102 of the lead frame.

All the copper strike plating layers of this Comparative Example 3 have the red matt appearance. As apparent from the X-ray diffraction pattern shown in FIG. 5, the X-ray diffraction intensities on the (111) planes of the copper strike plating layers of this Comparative Example 3 are weak rather than the diffraction intensity on (222) planes respectively.

Also, as apparent from the electron microphotographs in FIG. 6 showing the sectional structure of the copper strike plating layer of this Comparative Example 3, large metal crystals made of copper completely are formed and an upper surface of the copper strike plating layer is an uneven surface.

### EXAMPLE 5

(1) The lead frame was obtained as the substrate by applying the press working to the stripe member made of the Cu—Ni—Si alloy (Corson alloy) that contains Mg at 0.15 wt %. Then, the heat treatment was applied to remove the machining distortion of the lead frame. Only the alkaline degreasing process and the electrolytic activating process were applied to this lead frame.

Then, in the electrolytic copper plating equipment shown in FIG. 1, the lead frame to which only the degreasing process and the electrolytic activating process were applied was inserted as the substrate WE into the plating tab 30. Then, the copper strike plating was applied to the surface of the lead frame to get a thickness of 0.1 μm by applying the pulse current, the pulse period of which was set to 100 Hz and also the average current density (C.D.) of which was set to 7 A/dm², to the lead frame. At this time, the duty ratio was set to 0.4.

Then, the silver strike plating was applied to an upper surface of this copper strike plating layer. Then, the silver plating layer of 5 μm thickness was formed by the electrolytic silver plating at the current density (C.D.) of 120 A/dm².

(2) The polishing process, the degreasing process, the electrolytic activating process, and the acid treatment were applied to the lead frame used in the above (1). Then, the copper strike plating, the silver strike plating, and the electrolytic silver plating were applied in the similar manner to the above (1).

The heat resistance test was applied to respective lead frames, which were subjected to the copper strike plating, the silver strike plating, and the electrolytic silver plating in the above (1) and (2), by putting them on a hot plate heated at 400° C. for two minutes to heat. In this heat resistance test, it was examined whether or not the number of “occurrence of stain/discoloring” having a diameter of 100 μm or more and generated from the underlying layer and the “heating blister” of the plating layer were present. The results are given in following Table 5 as Example.

As Comparative Example, first the lead frames to which the plating was applied at following levels were obtained.

(I) In Comparative Example, the copper strike plating layer, the silver strike plating layer, and the silver plating layer were formed in the similar manner to Example 5(1) except that the copper strike plating was applied to the surface of the lead frame to get a thickness of 0.1 μm by applying the DC current whose current density (C.D.) was set to 7 A/dm².

(II) The polishing process, the degreasing process, the electrolytic activating process, and the acid treatment were applied to the lead frame used in the above (I). Then, the copper strike plating, the silver strike plating, and the electrolytic silver plating were applied similarly to the above (I).

The heat resistance test was applied to respective lead frames, which were subjected to the copper strike plating, the silver strike plating, and the electrolytic silver plating in the above (I) and (II), by putting them on the hot plate heated at 400° C. for two minutes to heat. In this heat resistance test, it was examined whether or not the number of “occurrence of stain/discoloring” having a diameter of 100 μm or more and generated from the underlying layer and the “heating blister” of the plating layer were present. The results are given in following Table 5 as Comparative Example.

TABLE 5

| | | Heat Resistance Test | |
|---|---|---|---|
| | Pretreatment | Occurrence of | Heating |
| | Step | Stain/Discoloring | Blister |
| Example | (I) No polishing | 11 | Generated |
| | (II) Polishing + Acid | 8 | Not |
| | Treatment | | |
| Comparative | (I) No polishing | 19 | Generated |
| Example | (II) Polishing + Acid | 26 | Generated |
| | Treatment | | |

In Example in Table 5, the “heating blister” was not generated by setting a thickness of the copper strike plating layer to 0.3 μm at the level where the “heating blister” was generated.

On the contrary, in Comparative Example in Table 5, even though a thickness of the copper strike plating layer was set to 0.3 μm at the level where the “heating blister” was generated, the “heating blister” was still generated.

As a result, it is appreciated that a heat resistance of the plated thin film could be improved at the level in Example rather than the level in Comparative Example.

What is claimed is:

1. A copper strike plating method comprising steps of:
applying a degreasing process and an activating process to a surface of a substrate made of a copper alloy that was subjected to a heat treatment; and
applying a copper strike plating to the surface of the substrate after the degreasing process and the activating process,
wherein, in the copper strike plating, a pulse current by which a current appears like a series of pulses only on a polarity side onto which a copper metal is deposited on the surface of the substrate is applied to the substrate such that a crystal plane showing a maximum value of an X-ray diffraction intensity of a copper strike plating layer formed on the surface of the substrate corresponds to a (111) plane as a crystal plane showing a maximum value of an X-ray diffraction intensity of a copper layer into which metal crystals made of copper are most densely filled.

2. A copper strike plating method according to claim 1, wherein the substrate obtained by applying only a degreasing process and an activating process to a substrate made of the copper alloy, which underwent a heat treatment, is employed as the substrate to which the strike plating is applied.

3. A copper strike plating method according to claim 1, wherein a pulse current, a pulse period and a duty ratio t_{ON}/(t_{ON}+t_{OFF}) (where t_{ON} is an ON time in which a current is supplied to the substrate, and t_{OFF} is an OFF time in which a current is shut off) of which are adjusted such that the crystal plane showing the maximum value of the X-ray diffraction intensity of the copper strike plating layer formed on the surface corresponds to the (111) plane, is employed as the pulse current.

4. A copper strike plating method according to claim 1, wherein the substrate made of the copper alloy that is formed by adding at least one element selected from a group consisting of Ni, Fe, Sn, Cr, Si and Mg to a matrix formed of copper is employed as the substrate.

5. A copper strike plating method according to claim 1, wherein a thickness of the copper strike plating layer is set to 0.01 to 5 μm.
